(19) United States
(12) Patent Application Publication
(10) Pub. No.: US 2026/0068581 A1
(43) Pub. Date: Mar. 5, 2026

(54) SUBSTRATE PROCESSING APPARATUS

(71) Applicant: SEMES CO., LTD., Cheonan-si (KR)

(72) Inventor: Byung Woo SIM, Seoul (KR)

(73) Assignee: SEMES CO., LTD., Cheonan-si (KR)

(21) Appl. No.: 19/307,740

(22) Filed: Aug. 22, 2025

(30) Foreign Application Priority Data
Aug. 28, 2024 (KR) 10-2024-0115523

(51) Int. Cl. H01L 21/67; B08B 13/00; B08B 15/02

(52) U.S. Cl. CPC H01L 21/67051; B08B 13/00; B08B 15/02

(57) ABSTRACT

Disclosed is an apparatus for processing a substrate, the apparatus including: a plurality of liquid treating chambers having a treatment space; and an exhaust unit for exhausting gas in the treatment space. The exhaust unit includes: a plurality of individual exhaust pipes connected to the liquid treating chamber, respectively; an exhaust damper installed in each individual exhaust pipe; a collective exhaust pipe connected with the individual exhaust pipe; a cleaning liquid supply unit for supplying a mist of the cleaning liquid to form a liquid curtain by the cleaning liquid; a cleaning liquid discharge pipe connected to the collective exhaust pipe; and a controller for controlling the cleaning liquid supply unit to supply a mist of the cleaning liquid in an abnormal exhaust state in which exhaust pressure applied to a point where the individual exhaust pipes are connected is higher than a set pressure.

### CROSS-REFERENCE TO RELATED APPLICATION

This application claims priority to and the benefit of Korean Patent Application No. 10-2024-0115523 filed in the Korean Intellectual Property Office on Aug. 28, 2024, the entire contents of which are incorporated herein by reference.

### TECHNICAL FIELD

The present invention relates to a substrate processing apparatus, and more particularly, to a substrate processing apparatus for exhausting a treatment space in a liquid treating chamber.

### BACKGROUND ART

To manufacture a semiconductor device or liquid crystal display, various processes, such as photolithography, etching, ashing, ion implantation, thin film deposition, and cleaning, are performed on a substrate. Among them, the cleaning process is performed in a liquid treating chamber that supplies a cleaning liquid on a rotating substrate and liquid treating the substrate.

When chemical is used as the cleaning liquid, fumes are generated during liquid treatment. Therefore, an individual exhaust pipe is connected to a general liquid treating chamber to exhaust fumes generated inside the liquid treating chamber, and an exhaust damper for adjusting the exhaust amount in each liquid treating chamber is installed in the individual exhaust pipe.

A plurality of liquid treating chambers is provided, and the individual exhaust pipes connected to the liquid treating chambers, respectively, are connected to a collective exhaust pipe. A constant exhaust pressure is applied to the collective exhaust pipe, and the internal pressure in the liquid treating chamber is changed while the process is performed in each liquid treating chamber by adjusting the exhaust damper installed in the individual exhaust pipe connected to each liquid treating chamber.

However, often external factors provide the collective exhaust pipe with exhaust pressure greater than the set pressure. In this case, it is difficult to control the exhaust pressure in the collective exhaust pipe in the typical device structure.

In addition, when fume or the like adhere to the collective exhaust pipe, it is difficult to accurately control the exhaust pressure, and there is a problem that the exhaust efficiency decreases.

### SUMMARY OF THE INVENTION

The present invention has been made in an effort to provide a substrate processing apparatus and a substrate processing method that improve substrate processing efficiency during a substrate processing process.

The present invention has also been made in an effort to provide a substrate processing apparatus and a substrate processing method capable of controlling exhaust pressure in a collective exhaust pipe during a substrate processing process.

The present invention has also been made in an effort to provide a substrate processing apparatus and a substrate processing method capable of controlling exhaust pressure in a collective exhaust pipe and removing fumes in the collective exhaust pipe during a substrate processing process.

The objectives of the present disclosure are not limited thereto and other objectives not stated herein may be clearly understood by those skilled in the art from the following description.

An exemplary embodiment of the present invention, an apparatus for processing a substrate, the apparatus comprising: a plurality of liquid treating chambers that have a treatment space and supply a treatment liquid to a substrate disposed in the treatment space to perform liquid treatment on the substrate; and an exhaust unit for exhausting gas in the treatment space of the plurality of liquid treating chambers, wherein the exhaust unit includes: a plurality of individual exhaust pipes connected to the liquid treating chambers, respectively, and each having a separate exhaust passage through which gas exhausted from the treatment space flows; a plurality of exhaust dampers installed in the plurality of individual exhaust pipes, respectively, to control opening rates of the individual exhaust passages; a collective exhaust pipe connected with the plurality of individual exhaust pipes, and having a collective exhaust passage through which gas exhausted through the plurality of individual exhaust pipes flows; a cleaning liquid supply unit having a cleaning nozzle that is provided to the collective exhaust pipe and that supplies a mist of the cleaning liquid to form a liquid curtain by the cleaning liquid in the collective exhaust passage; a cleaning liquid discharge pipe connected to the collective exhaust pipe and discharging the cleaning liquid supplied from the cleaning liquid supply unit to the collective exhaust passage; and a controller for controlling the cleaning liquid supply unit, and the controller may controls the cleaning liquid supply unit to supply the mist of the cleaning liquid from the cleaning liquid supply unit in an abnormal exhaust state in which exhaust pressure applied to a point where the individual exhaust pipes are connected from upstream in the collective exhaust pipe is higher than a set pressure.

According to the exemplary embodiment of the present invention, wherein the exhaust unit further may include an outside air introduction unit provided in the collective exhaust pipe to introduce outside air into the collective exhaust passage.

According to the exemplary embodiment of the present invention, the controller may controls the cleaning liquid supply unit to adjust an area occupied by the mist in a cross section perpendicular to a length direction of the collective exhaust pipe in the collective exhaust passage based on a magnitude of a difference between the exhaust pressure and the set pressure.

According to the exemplary embodiment of the present invention, the cleaning nozzle is a two-fluid nozzle that supplies the cleaning liquid and gas for misting the cleaning liquid, and the controller may controls the cleaning liquid supply unit to adjust the pressure of the gas to adjust the area occupied by the mist of the cleaning liquid discharged from the cleaning nozzle.

According to the exemplary embodiment of the present invention, the controller first controls an opening rate of the outside air introduction unit before supplying the mist of the cleaning liquid when the exhaust pressure is higher than the set pressure, and may controls the cleaning liquid supply unit to supply the mist of the cleaning liquid when the exhaust pressure is higher than the set pressure even after the opening rate of the outside air introduction unit is maximum.

According to the exemplary embodiment of the present invention, the controller first controls an opening rate of the exhaust damper before supplying the mist of the cleaning liquid when the exhaust pressure is higher than the set pressure, and may controls the cleaning liquid supply unit to supply the mist of the cleaning liquid when the exhaust pressure is higher than the set pressure even after the opening rate of the exhaust damper is maximum.

According to the exemplary embodiment of the present invention, the controller first controls an opening rate of the outside air introduction unit and an opening rate of the exhaust damper before supplying the mist of the cleaning liquid when the exhaust pressure is higher than the set pressure, and may controls the cleaning liquid supply unit to supply the mist of the cleaning liquid when the exhaust pressure is higher than the set pressure even after the opening rate of the outside air introduction unit and the opening rate of the exhaust damper are maximum.

According to the exemplary embodiment of the present invention, the controller may controls the cleaning liquid supply unit so that the pressure of the gas increases as the difference between the exhaust pressure and the set pressure increases.

According to the exemplary embodiment of the present invention, the outside air introduction unit may be located upstream from the cleaning nozzle and is located downstream from the point where the individual exhaust pipes are connected.

According to the exemplary embodiment of the present invention, the controller further may controls the cleaning liquid supply unit to periodically supply the mist of the cleaning liquid during processing of the substrate in the liquid treating chamber in a normal exhaust state in which the exhaust pressure is equal to the set pressure.

According to the exemplary embodiment of the present invention, the cleaning nozzle and the cleaning liquid discharge pipe may be disposed to face each other in a vertical direction.

According to the exemplary embodiment of the present invention, the cleaning liquid discharge pipe includes: a liquid inlet portion including an entrance of the cleaning liquid discharge pipe; and a discharge pipe portion extending from an end of the liquid inlet portion and having a constant passage area along a longitudinal direction thereof, and the liquid inlet portion may be provided to gradually expand a cross-sectional area in a direction from the discharge pipe portion toward the entrance of the cleaning liquid discharge pipe.

An exemplary embodiment of the present invention, an apparatus for processing a substrate, the apparatus comprising: a liquid treating chamber that has a treatment space and supplies a treatment liquid to a substrate disposed in the treatment space to perform liquid treatment on the substrate; and an exhaust unit for exhausting gas in the treatment space of the liquid treating chamber, wherein the exhaust unit includes: an individual exhaust pipe connected to the liquid treating chamber and having an exhaust passage through which gas exhausted from the treatment space flows; an exhaust damper installed in the individual exhaust pipe to control an opening rate of the individual exhaust passage; a cleaning liquid supply unit having a cleaning nozzle that is provided to the individual exhaust pipe and that supplies a mist of the cleaning liquid to form a liquid curtain by the cleaning liquid in the individual exhaust passage; a cleaning liquid discharge pipe connected to the individual exhaust pipe and discharging the cleaning liquid supplied from the cleaning liquid supply unit to the individual exhaust passage; and a controller for controlling the cleaning liquid supply unit, and the controller may controls the cleaning fluid liquid unit to supply the mist of the cleaning liquid from the cleaning liquid supply unit to the individual exhaust passage in an abnormal exhaust state, in which an exhaust pressure applied to the individual exhaust pipe downstream from the exhaust damper in the individual exhaust passage of the individual exhaust pipe is higher than a set pressure.

According to the exemplary embodiment of the present invention, the exhaust unit further may includes an outside air introduction unit provided in the individual exhaust pipe to introduce outside air into the individual exhaust passage.

According to the exemplary embodiment of the present invention, the controller may controls the cleaning liquid supply unit to adjust an area occupied by the mist of the cleaning liquid supplied from the cleaning nozzle in a cross section perpendicular to a length direction of the individual exhaust passage in the individual exhaust passage based on a magnitude of a difference between the exhaust pressure and the set pressure.

According to the exemplary embodiment of the present invention, the cleaning nozzle is a two-fluid nozzle that supplies the cleaning liquid and gas for misting the cleaning liquid, and the controller may controls the cleaning liquid supply unit to adjust the pressure of the gas to adjust the area occupied by the mist of the cleaning liquid discharged from the cleaning nozzle.

According to the exemplary embodiment of the present invention, the outside air introduction unit may be located upstream from the cleaning nozzle and is located downstream from the exhaust damper.

According to the exemplary embodiment of the present invention, the cleaning liquid discharge pipe includes: a liquid inlet portion including an entrance of the cleaning liquid discharge pipe; and a discharge pipe portion extending from an end of the liquid inlet portion and having a constant passage area along a longitudinal direction thereof, and an area of the entrance of the cleaning liquid discharge pipe is provided larger than an area of a passage of the discharge pipe portion, and the cleaning nozzle and the cleaning liquid discharge pipe may be disposed to face each other in a vertical direction.

According to the exemplary embodiment of the present invention, the controller may controls the cleaning liquid supply unit to periodically supply the mist of the cleaning liquid during processing of the substrate in the liquid treating chamber in a normal exhaust state in which the exhaust pressure is equal to the set pressure.

An exemplary embodiment of the present invention, an apparatus for processing a substrate, the apparatus comprising: a plurality of liquid treating chambers that have a treatment space and supply a treatment liquid to a substrate disposed in the treatment space to perform liquid treatment on the substrate; and an exhaust unit for exhausting gas in the treatment space of the plurality of liquid treating chambers, wherein the exhaust unit includes: a plurality of individual exhaust pipes connected to the liquid treating chambers, respectively, and each having a separate exhaust passages through which gas exhausted from the treatment space flows; a plurality of exhaust dampers installed in the plurality of individual exhaust pipes to control opening rates of the individual exhaust passages, respectively; a collective exhaust pipe connected with the plurality of individual exhaust pipes, and having a collective exhaust passage through which gas exhausted through the plurality of individual exhaust pipes flows; an outside air introduction unit provided in the collective exhaust pipe and introducing outside air into the collective exhaust passage; a cleaning liquid supply unit with a cleaning nozzle that is provided to the collective exhaust pipe and that supplies a mist of the cleaning liquid to form a liquid curtain by the cleaning liquid in the collective exhaust passage; a cleaning liquid discharge pipe connected to the collective exhaust pipe and discharging the cleaning liquid supplied from the cleaning liquid supply unit to the collective exhaust passage; and a controller for controlling the cleaning liquid supply unit, and wherein the controller controls the cleaning liquid supply unit to supply the mist of the cleaning liquid from the cleaning liquid supply unit in an abnormal exhaust state in which exhaust pressure applied to a point where the individual exhaust pipes are connected from upstream in the collective exhaust pipe is higher than a set pressure, and controls the cleaning liquid supply unit to periodically supply the mist of the cleaning liquid during processing of the substrate in the liquid treating chamber in a normal exhaust state in which the exhaust pressure is equal to the set pressure.

According to the exemplary embodiment of the present invention, it is possible to improve substrate processing efficiency.

In addition, according to the exemplary embodiment of the present invention, it is possible to adjust the exhaust pressure in the collective exhaust pipe.

In addition, according to the exemplary embodiment of the present invention, it is possible to adjust the exhaust pressure in the collective exhaust pipe and remove fumes in the collective exhaust pipe.

Effects of the present disclosure are not limited to those described above and effects not stated above will be clearly understood to those skilled in the art from the specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a top plan view schematically illustrating a substrate processing apparatus according to an exemplary embodiment of the present invention.

FIG. 2 is a diagram schematically illustrating an exemplary embodiment of a liquid treating chamber of FIG. 1.

FIG. 3 is a diagram schematically illustrating an exemplary embodiment of an exhaust unit connected to the liquid treating chamber of FIG. 2.

FIG. 4 is a cross-sectional view illustrating an example of a cleaning nozzle of FIG. 3.

FIG. 5 is a flowchart illustrating an example of an exhaust adjusting process of an exhaust unit.

FIG. 6 is a cross-sectional view schematically illustrating a cross section of a collective exhaust passage in a mist discharge operation.

FIGS. 7 and 8 are diagrams schematically illustrating another exemplary embodiment of the exhaust unit of FIG. 3.

FIG. 9 is a cross-sectional view schematically illustrating another exemplary embodiment of the cleaning nozzle of FIG. 4.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

An expression, “and/or” includes each of the mentioned items and all of the combinations including one or more of the items. Further, in the present specification, “connected” means not only when member A and member B are directly connected, but also when member A and member B are indirectly connected by interposing member C between member A and member B.

Embodiments of the present disclosure may be modified in various ways and the scope of the present disclosure should not be construed as being limited to the embodiments to be described below. Embodiments are provided to more completely explain the present disclosure to those skilled in the art. Accordingly, the shapes of the components shown in the figures are exaggerated to enhance clearer description.

In the present invention, a wafer used for manufacturing a semiconductor is described as an example of a substrate. However, unlike this, the substrate may be a mask or a flat panel display panel.

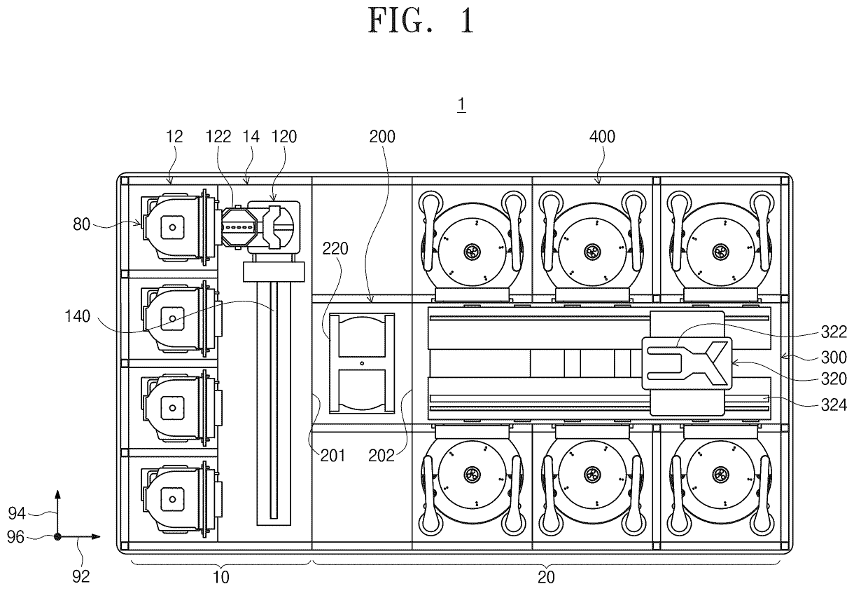

FIG. 1 is a top plan view schematically illustrating a substrate processing apparatus according to an exemplary embodiment of the present invention.

Referring to FIG. 1, a substrate processing apparatus includes an index module 10 and a treating module 20. According to an example, the index module 10 and the treating module 20 are disposed along one direction. Hereinafter, the direction in which the index module 10 and the treating module 20 are disposed is referred to as a first direction 92, and when viewed from above, a direction perpendicular to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely processed in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 94.

An index robot 120 is provided to the index frame 14. A guide rail 140 of which a longitudinal direction is the second direction 94 is provided within the index frame 14, and the index robot 120 may be provided to be movable on the guide rail 140. The indexing robot 120 includes a hand 122 on which the substrate W is placed, and the hand 122 may be provided to be movable forward and backward, rotatable about the third direction 96, and movable along the third direction 96. The plurality of hands 122 is provided while being spaced apart from each other in the vertical direction, and is capable of independently moving forward and backward.

The treating module 20 includes a buffer unit 200, a transfer chamber 300, a liquid treating chamber 400, and an exhaust unit 500.

The buffer unit 200 provides a space in which the substrate W loaded into the treating module 20 and the substrate W unloaded from the treating module 20 stay temporarily. The liquid treating chamber 400 performs a processing process of liquid treating the substrate W by supplying a liquid onto the substrate W. The transfer chamber 300 transfers the substrate W between the buffer unit 200 and the liquid treating chamber 400.

The transfer chamber 300 may be provided so that a longitudinal direction is the first direction 92. The buffer unit 200 may be disposed between the index module 10 and the transfer chamber 300. A plurality of liquid treating chambers 400 may be provided and may be disposed on the side portion of the transfer chamber 300. The liquid treating chamber 400 and the transfer chamber 300 may be disposed in the second direction 94. The buffer unit 200 may be located at one end of the transfer chamber 300.

According to the example, the liquid treating chambers 400 are respectively disposed on opposite sides of the transfer chamber 300. At one side of the transfer chamber 300, the liquid treating chambers 400 may be provided in an array of A×B (A and B are each 1 or a natural number larger than 1) in the first direction 92 and the third direction 96. A plurality of liquid treating chambers may be provided in a structure stacked in the third direction.

The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 96, and movable along the third direction 96. The plurality of hands 322 is provided while being spaced apart from each other in the vertical direction, and is capable of independently moving forward and backward.

The buffer unit 200 includes a plurality of buffers 220 on which the substrate W is placed. The buffers 220 may be disposed while being spaced apart from each other in the third direction 96. A front face 201 and a rear face 202 of the buffer unit 200 are opened. The front face 201 of the buffer unit is a face facing the index module 10, and the rear face 202 of the buffer unit is a face facing the transfer chamber 300. The index robot 120 may approach the buffer unit 200 through the front face 201 of the buffer unit, and the transfer robot 320 may approach the buffer unit 200 through the rear face 202 of the buffer unit.

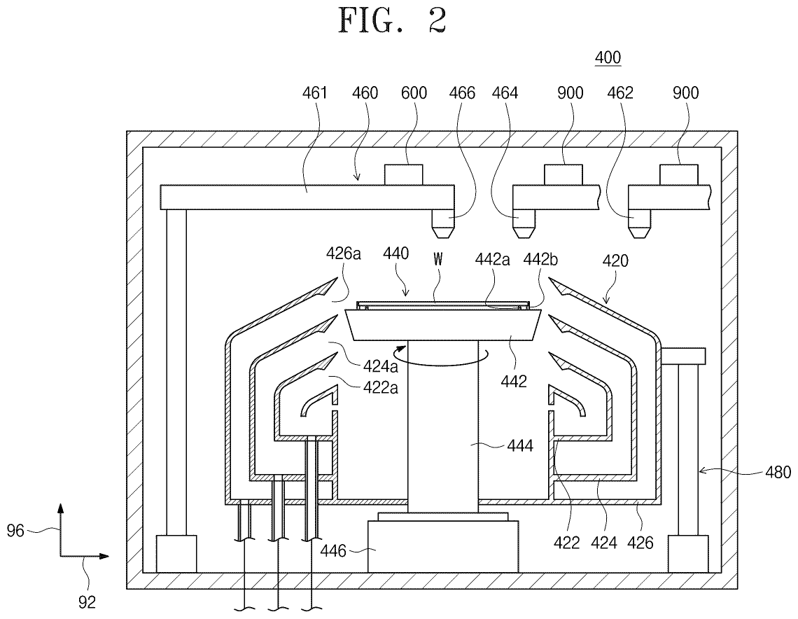

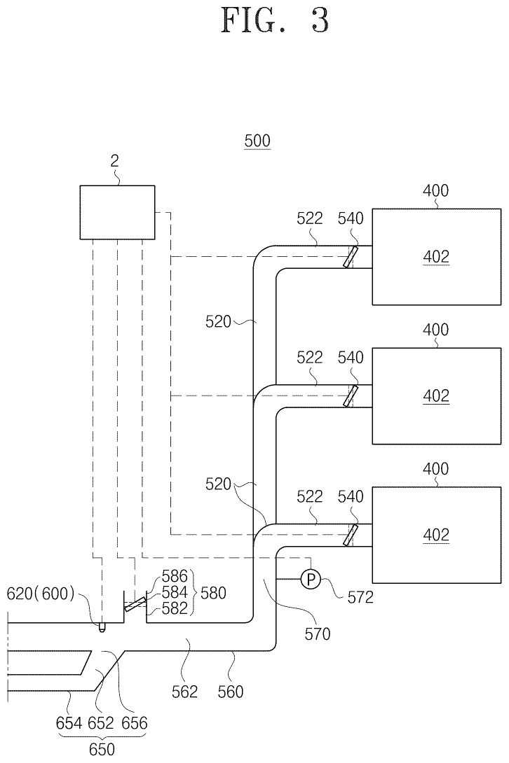

The liquid treating chamber 400 and the exhaust unit 500 will be described below with reference to FIGS. 2 and 3.

FIG. 2 is a diagram schematically illustrating one example of the liquid treating chamber of FIG. 1.

Referring to FIG. 2, the liquid treating chamber 400 includes a housing 410, a cup 420, a support unit 440, a nozzle unit 460, and a lifting unit 480.

The housing 410 is provided in a generally rectangular parallelepiped shape. The cup 420, the support unit 440, and the nozzle unit 460 are disposed within the housing 410. A fan filter unit 470 is disposed on an upper wall of the housing 410.

The fan filter unit 470 generates a descending airflow inside the housing 410. The fan filter unit 410 may have a filter and a fan. The fan introduces external gas into the treatment space, and the filter removes particles remaining in the external air. The descending airflow introduced by the fan filter unit 410 provides a uniform airflow over the substrate. Fumes generated from the treatment liquid in the process of processing the surface of the substrate W are exhausted to the outside of the treatment space 402 through the exhaust unit 500 together with the gas introduced into the treatment space 402.

The cup unit 420 has a treatment space 402 in which an upper portion is opened. The cup unit 420 includes an inner cup 422, an intermediate cup 424, and an outer cup 426. The inner cup 422, the intermediate cup 424, and the outer cup 426 each have recovery spaces for recovering a liquid used for processing the substrate W. The inner cup 422, the intermediate cup 424, and the outer cup 426 are each provided in a ring shape surrounding the support unit 440. When the liquid treatment process is performed, the treatment liquid scattered by rotation of the substrate W flows into the recovery space through the inlets 422a, 424a, and 426a of the inner cup 422, the intermediate cup 424, and the outer cup 426. According to the exemplary embodiment, the inner cup 422 is disposed to surround the support unit 440, the intermediate cup 424 is disposed to surround the inner cup 422, and the outer cup 426 is disposed to surround the intermediate cup 424. The intermediate cup inlet 424a through which the liquid flows into the intermediate cup 424 may be positioned above the inner cup inlet 422a through which the liquid flows into the inner cup 422, and the outer cup inlet 426a through which the liquid flows into the outer cup 426 may be positioned above the intermediate cup inlet 424a through which the liquid flows into the intermediate cup 424.

The support unit 440 supports the substrate W in the treatment space. The support unit 440 includes a support plate 442 and a drive shaft 444. An upper surface of the support plate 442 may be provided in a generally circular shape, and may have a diameter larger than a diameter of the substrate W. A chuck pin 442b is provided at an edge of the support plate 442. The chuck pin 442b is provided to protrude upward from the support plate 442, and supports a side portion of the substrate W so that the substrate W is not separated from the supporting unit 440 when the substrate W is rotated. Further, a support pin 442a for supporting a rear surface of the substrate W is provided on the support plate, and an upper end of the support pin 442a thereof protrudes from the support plate 442 such that the substrate W is spaced apart from the support plate 442 by a predetermined distance. The support pin 442a is disposed closer to a center of the support plate 442 than the chuck pin 442b. The drive shaft 444 is driven by the driver 446, is connected to a center of a bottom surface of the substrate W, and rotates the support plate 442 with respect to its central axis.

The nozzle unit 460 supplies a liquid onto the substrate W supported on the support unit 440. The liquid may be provided in a plurality of types, and may be sequentially supplied onto the substrate W. The nozzle unit 460 includes a first nozzle 462, a second nozzle 464, and a third nozzle 466. The first nozzle 462 supplies a treatment liquid of a first component onto the substrate W. The treatment liquid of the first component may be a liquid for removing a film or foreign substances remaining on the substrate W. For example, the treatment liquid of the first component may be a chemical of an acid component, such as sulfuric acid, hydrofluoric acid, phosphoric acid, or hydrochloric acid, a chemical of an alkali component, such as ammonia, or a mixture of an acid component and an alkali component. The second nozzle supplies a treatment liquid of a second component onto the substrate W. For example, the treatment liquid of the second component may be an organic solvent. The organic solvent may be isopropyl alcohol (IPA). The third nozzle supplies a treatment liquid of a third component onto the substrate W. For example, the treatment liquid of the third component may be water. The first nozzle 462, the second nozzle 464, and the third nozzle 466 are supported by different arms 461, and these arms 461 may be moved independently. Selectively, the first nozzle 462, the second nozzle 464, and the third nozzle 466 may be mounted on the same arm 461 and simultaneously moved.

The lifting unit 480 adjusts a relative height between the cup 420 and the support unit 440. The lifting unit 480 moves the cup 420 in the up and down direction. By the up and down movement of the cup 420, a relative height between the cup 420 and the substrate W is changed. Accordingly, the recovery containers 422, 424, and 426 for recovering the treatment liquid are changed according to the type of liquid supplied to the substrate W, and thus the liquids may be separated and recovered. Unlike the description, the cup 420 is fixedly installed, and the lifting unit 480 may move the support unit 440 in the up and down direction.

FIG. 3 is a diagram schematically illustrating the configuration of the exhaust unit connected to the liquid treating chamber of FIG. 2.

The exhaust unit 500 exhausts gas in the treatment space 402 of the liquid treating chamber 400. Referring to FIG. 3, the exhaust unit 500 includes an individual exhaust pipe 520, an exhaust damper 540, a collective exhaust pipe 560, an outside air introduction unit 580, a cleaning liquid supply unit 600, a cleaning liquid discharge pipe 650, and a controller 2.

A plurality of liquid treating chambers 400 is provided. According to the exemplary embodiment, three liquid treating chambers 400 may be provided. The individual exhaust pipes 520 are connected to the liquid treating chambers 400, respectively. An individual exhaust passage 522 is formed in the individual exhaust pipe 520. The gas exhausted from the treatment space 402 flows through the individual exhaust passage 522.

The lowest downstream point among the connection points where which individual exhaust pipes 520 are connected in the collective exhaust pipe 560 is referred to as a first point 570. A pressure sensor 572 is installed at the first point 570 of the collective exhaust pipe 560.

The exhaust damper 540 is installed in each of the individual exhaust pipes 520. The exhaust damper 540 may be provided in a disk shape. The exhaust damper 540 adjusts an opening rate of the individual exhaust passage 522. The exhaust damper 540 may be rotated with respect to a central axis thereof by a driver (not Illustrated).

The collective exhaust pipe 560 is connected to a plurality of individual exhaust pipes 520. The collective exhaust pipe 560 may be connected to a downstream factory exhaust duct. A collective exhaust passage 566 is formed in the collective exhaust pipe 560.

The outside air introduction unit 580 introduces outside air from the outside to the collective exhaust passage 562. The outside air introduction unit 580 includes an outside air introduction pipe 582 and an outside air introduction damper 584. The outside air introduction pipe 582 is connected to the collective exhaust pipe 560. An outside air introduction passage 586 through which outside air may flow is formed in the outside air introduction pipe 582. The outside air introduction damper 584 is installed in the outside air introduction pipe 582. The outside air introduction damper 584 may be provided in a disk shape. The outside air introduction damper 584 may adjust the amount of outside air introduced into the outside air introduction pipe 582 by adjusting an opening rate of the inlet of the outside air introduction pipe 582. The outside air introduction damper 584 may be rotated with respect to a central axis thereof by a driver (not illustrated).

The cleaning liquid supply unit 600 includes a cleaning liquid supply source 602, a cleaning liquid supply pipe 604, a gas supply source 606, a gas supply pipe 608, and a cleaning nozzle 620. The cleaning liquid supply unit 600 forms a liquid curtain by supplying a cleaning liquid to the collective exhaust passage 562. The cleaning liquid supply unit 600 may supply the cleaning liquid in a form of a mist.

The cleaning liquid supply source 602 stores the cleaning liquid. The cleaning liquid supply pipe 604 connects the cleaning liquid supply source 602 to the cleaning nozzle 620. The cleaning liquid is supplied from the cleaning liquid supply source 602 to the cleaning nozzle 620 through the cleaning liquid supply pipe 604. An opening/closing valve 605 and a pump (not illustrated) are installed in the cleaning liquid supply pipe 604. The gas supply pipe 606 stores gas. The gas supply pipe 608 connects the gas supply source 606 to the cleaning nozzle 620. The gas is supplied from the gas supply source 606 to the cleaning nozzle 620 through the gas supply pipe 608. An opening/closing valve 609 and a flow rate control valve 610 are installed in the gas supply pipe 608.

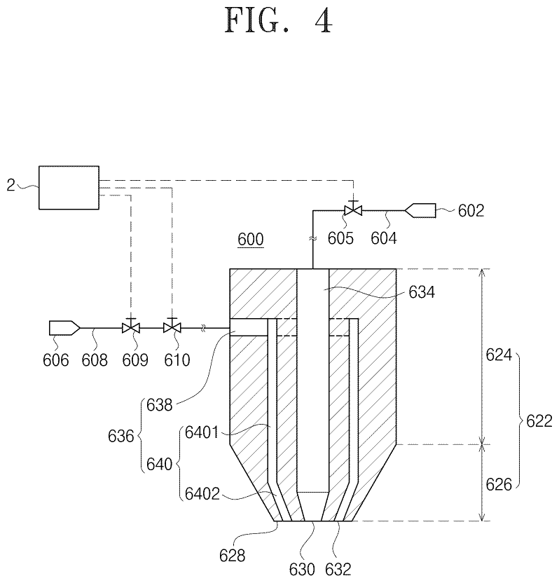

FIG. 4 is a cross-sectional view illustrating an example of the cleaning nozzle of FIG. 3.

Referring to FIG. 4, the cleaning nozzle 620 includes a body 622. The body 622 has an upper body 624 and a lower body 626. The upper body 624 may be provided in a cylindrical shape. The lower body 626 extends downward from the upper body 624. The lower body 626 has a shape in which a longitudinal section becomes narrower as it goes downward. In one exemplary embodiment, the lower body 626 may be provided in a conical shape. A cleaning liquid discharge port 630 and a gas discharge port 632 are formed on a lower surface 628 of the lower body 626. In one exemplary embodiment, a plurality of gas discharge ports 632 may be formed to surround the cleaning liquid discharge port 630.

A cleaning liquid flow path 634 and a gas flow path 636 are formed in the body 622. A cleaning liquid supply pipe 604 is connected to the cleaning liquid flow path 634. The cleaning liquid flow path 634 supplies the cleaning liquid supplied from the cleaning liquid supply pipe 604 to the collective exhaust passage 562. In one exemplary embodiment, the cleaning liquid may be water. The cleaning liquid flow path 634 is formed in a linear direction from the upper body 624 to the end of the lower body 626. A gas supply pipe 608 is connected to the gas flow path 636. The gas flow path 636 supplies the gas supplied from the gas supply pipe 608 to the collective exhaust passage 562. In one exemplary embodiment, the gas may be nitrogen (N2) or air. The gas flow path 636 is formed from the side portion of the upper body 624 to the end of the lower body 626. In one exemplary embodiment, a plurality of gas flow paths 636 may be provided. The gas flow path 636 includes an annular flow path 638 connecting a plurality of flow paths 640. The gas flow path 636 is divided into an upper part 6401 and a lower part 6402 according to the direction in which the flow path is formed. The annular flow path 638 is formed on the upper part 6401 side of the gas flow path 636. The upper part 6401 of the gas flow path 636 is formed in a direction parallel to the cleaning liquid flow path 634 mainly in the upper body 624. The lower part 6402 of the gas flow path 636 is formed to be inclined in the direction closer to the cleaning liquid discharge port 630 mainly in the lower body 626. With this structure, when the cleaning liquid and gas are simultaneously discharged from the cleaning nozzle 620, the cleaning liquid is misted by the pressure of the gas.

The cleaning liquid discharge pipe 650 is connected to the collective exhaust pipe 560. The cleaning liquid discharge pipe 650 discharges the cleaning liquid discharged through the collective exhaust passage 562 to the outside. The cleaning liquid discharge pipe 560 and the cleaning nozzle 620 may be provided at positions facing each other in the vertical direction. The cleaning liquid discharge pipe 650 includes a liquid inlet portion 652 and a discharge pipe portion 654.

The liquid inlet portion 652 is formed in a downward direction from the collective exhaust pipe 560. The liquid inlet portion 652 introduces the cleaning liquid into the cleaning liquid discharge pipe 650. The liquid inlet portion 652 is provided in the shape of a circular hole when viewed from the top. In one exemplary embodiment, the liquid inlet portion 652 may be formed to gradually widen a cross-sectional area in a direction from the discharge pipe portion 654 toward an entrance 656 of the cleaning liquid discharge pipe 650. In one exemplary embodiment, the liquid inlet portion 652 may be provided to be inclined in a direction toward the upstream of the collective exhaust pipe 560 as the distance from the discharge pipe portion 654 increases.

The discharge pipe portion 654 discharges the cleaning liquid introduced from the liquid inlet portion 652 to the outside. The discharge pipe portion 654 is provided in a direction parallel to the collective exhaust pipe 560. The discharge pipe portion 654 is provided to have a smaller cross-sectional area than the liquid inlet portion 652.

The controller 2 controls the substrate processing apparatus 1. The controller 2 may include a process controller, a keyboard, a user interface, a control program, and a storage unit. The process controller controls the substrate processing apparatus 1. The process controller consists of a microprocessor (computer). The keyboard performs command input and operation for the operator to manage the substrate processing apparatus 1. The user interface is composed of a display that visualizes and displays the operation status of the substrate processing apparatus 1. The control program executes processing executed on the substrate processing apparatus 1 under the control of the process controller. The storage unit executes processing to each component according to various data and processing conditions. The user interface and the storage unit may be connected to the process controller. The storage medium may be provided as a portable disk, such as a hard disk, a CD-ROM, or a DVD, or a semiconductor memory, such as a flash memory.

The controller 2 controls the opening/closing valve 605 installed in the cleaning liquid supply pipe 604, the opening/closing valve 609 installed in the gas supply pipe 608, the flow control valve 610, the outside air introduction damper 584, and the exhaust damper 540.

Hereinafter, the exhaust control process of the exhaust unit of FIG. 3 will be described in detail.

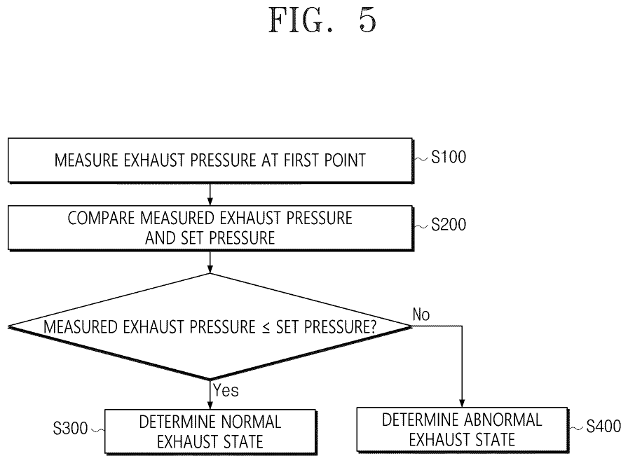

FIG. 5 is a flowchart illustrating an example of an exhaust adjusting process of the exhaust unit.

Referring to FIG. 5, while the substrate W is processed in the treatment space 402 using a treatment liquid, the treatment space 402 is exhausted. Accordingly, gas generated in the process of liquid-treating the substrate W in the treatment space 402 sequentially flows through the individual exhaust pipe 520 and the collective exhaust pipe 560. A preset pressure is applied to the collective exhaust pipe 560 at the downstream side thereof.

The pressure sensor 572 installed at the first point 570 of the collective exhaust passage 562 measures an exhaust pressure applied to the collective exhaust passage 562, and transmits the measured exhaust pressure value to the controller 2 (S100). The controller 2 determines whether the exhaust state is normal according to the difference between the exhaust pressure measured at the first point 570 and the set pressure (S200). The controller 2 determines that the exhaust state is a normal exhaust state when the exhaust pressure measurement value at the first point 570 and the set pressure are equal to or lower than the set pressure (S300). Here, the case where the exhaust pressure measurement value and the set pressure are the same includes not only the case where the measurement value and the set pressure are exactly the same, but also the case where a difference between the exhaust pressure measurement value and the set pressure is within a predetermined range. Furthermore, when the exhaust pressure measurement value at the first point 570 is higher than the set pressure, the controller 2 determines that the exhaust state is an abnormal exhaust state (S400).

When the controller 2 determines that the exhaust state is the normal exhaust state (S300), the controller 2 controls the exhaust unit 500 as follows.

First, the exhaust damper 540 is adjusted so that an appropriate amount of gas generated by processing the substrate W in each liquid treating chamber 400 is exhausted. The opening rate of the exhaust damper 540 may be adjusted based on process operations performed in each liquid treating chamber 400. The process operations may be operations according to the processing period of the substrate W, such as loading the substrate W, liquid treatment, drying, and unloading the substrate W. Selectively, the opening rate of the exhaust damper 540 may be adjusted based on the type of chemical used for processing the substrate W. Selectively, the supply amount of airflow from the fan filter unit 470 and/or the opening rate of the exhaust damper 540 may be adjusted so that the pressure of the treatment space 402 maintains a preset pressure.

When the sum of the exhaust amounts exhausted from all liquid treating chambers 400 during the processing of the substrate W is smaller than the set amount, the outside air is introduced into the collective exhaust pipe 560 through the outside air introduction unit 580 by the difference. The amount of outside air introduced may be determined based on the number of liquid treating chambers 400 in use. Optionally, the amount of outside air introduced may be determined based on the opening rate of each exhaust damper 540. Optionally, the amount of outside air introduced may be determined based on the number of liquid treating chambers 400 in use and the opening rate of each exhaust damper 540.

In the normal exhaust state, the mist of the cleaning liquid is periodically discharged from the cleaning nozzle 620 while the gas is exhausted through the collective exhaust passage 560. While the mist of the cleaning liquid is discharged, fumes contained in the gas exhausted through the collective exhaust passage 562 are discharged through the cleaning liquid discharge pipe 650 together with the cleaning liquid. Accordingly, it is possible to reduce the deposition of fumes in the collective exhaust pipe 560 and the influence on exhaust pressure.

The discharge period in which the mist of the cleaning liquid is discharged may be set in various ways.

For example, the discharge period may be determined based on the number of liquid treating chambers 400 in which the processing of the substrate W is performed. The discharge period may be selectively determined based on the type of chemical used for processing the substrate W in each liquid treating chamber 400. In an exemplary embodiment, the amount of supplied gas when the cleaning liquid is periodically discharged may be 50 L/min to 150 L/min.

When it is determined that the exhaust state is the abnormal exhaust state (S400), the controller 2 adjusts the exhaust unit 500 as follows.

When it is determined that the exhaust state is the abnormal exhaust state (S400), an outside air introduction amount adjusting operation is performed first.

In the outside air introduction amount adjusting operation, the amount of outside air introduction is adjusted based on the difference between the exhaust pressure measurement value and the set pressure. For example, as the difference between the exhaust pressure measurement value and the set pressure increases, the amount of outside air introduction increases. According to the difference between the exhaust pressure and the set pressure, the amount of outside air introduction corresponding thereto may be preset.

When the difference between the exhaust pressure measurement value and the set pressure is greater than the maximum corresponding value corresponding to the maximum amount of outside air introduction, a mist discharge operation of discharging the mist of the cleaning liquid is performed. In the mist discharge operation, the supply amount of cleaning liquid and gas is adjusted so that the area occupied by the mist is adjusted based on the difference between the exhaust pressure measurement value and the set pressure. The area occupied by the mist may be an occupied area when viewed from a cross section perpendicular to the length direction of the collection exhaust passage 562. For example, as the difference between the exhaust pressure measurement value and the set pressure increases, the supply amount of gas may increase without changing the supply amount of the cleaning liquid. Optionally, as the difference between the exhaust pressure measurement value and the set pressure increases, both the supply amount of cleaning liquid and the supply amount of gas may increase.

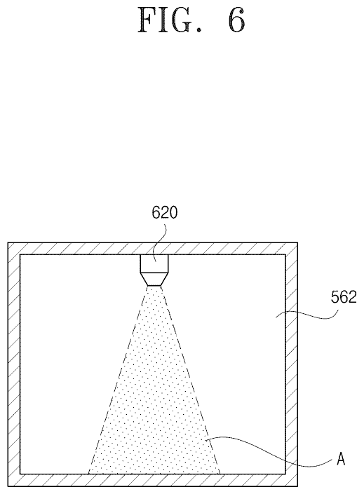

FIG. 6 is a cross-sectional view schematically illustrating a cross section of the collective exhaust passage in a mist discharge operation.

Referring to FIG. 6, in the mist discharge operation, the cleaning nozzle 620 sprays the cleaning liquid and gas so that the area occupied by the mist in the collective exhaust passage 562 is adjusted based on the difference between the exhaust pressure and the set pressure. As the pressure of the gas injected through the cleaning nozzle 620 increases, the cleaning liquid is misted into smaller particles. Accordingly, as the pressure of the gas injected through the cleaning nozzle 620 increases, the area A in which the mist spreads is widened. The mist forms a liquid curtain in the collective exhaust passage 562. As the pressure of the injected gas increases, the mist forms a liquid curtain over a wide area in the collective exhaust passage 562. In the area in which the liquid curtain is formed, the flow of exhaust is hindered.

According to another example, when it is determined that the exhaust state is the abnormal exhaust state (S400), the exhaust damper adjusting operation may be performed first.

In the exhaust damper adjusting operation, an opening rate of the exhaust damper is adjusted based on a difference between the exhaust pressure measurement value and the set pressure. For example, an opening rate of the exhaust damper is increased as a difference between the exhaust pressure measurement value and the set pressure is increased. An opening rate of the exhaust damper corresponding to the difference between the exhaust pressure and the set pressure may be set in advance.

When the difference between the exhaust pressure measurement value and the set pressure is greater than the maximum corresponding value corresponding to the maximum opening rate of the exhaust damper, the outside air introduction amount adjusting operation is performed. Thereafter, when the difference between the exhaust pressure measurement value and the set pressure is still greater than the corresponding value corresponding to the maximum amount of outside air introduction, the mist discharge operation is performed.

According to another example, when it is determined that the exhaust state is the abnormal exhaust state (S400), the exhaust damper adjusting operation and the outside air introduction amount adjusting operation may be performed together.

In this case, according to the difference between the exhaust pressure and the set pressure, the amount of outside air introduction and the opening rate of the exhaust damper corresponding to the difference may be set in advance.

When the difference between the exhaust pressure measurement value and the set pressure is greater than the maximum response value corresponding to the maximum opening rate of the exhaust damper, or the difference between the exhaust pressure measurement value and the set pressure is greater than the maximum response value corresponding to the maximum amount of outside air introduction, the mist discharge operation is performed.

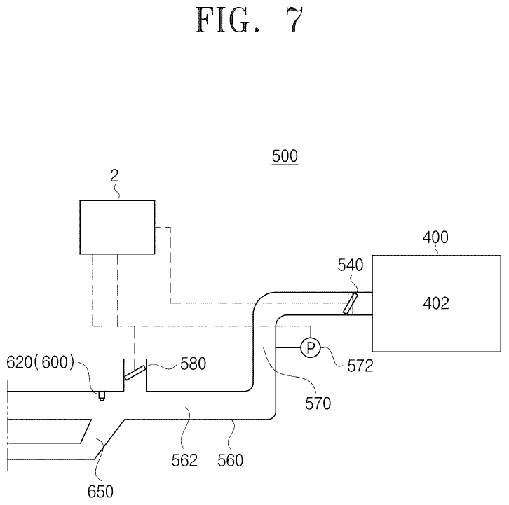

In the above example, the present invention has been described based on the case where in the structure in which the individual exhaust pipes 520 connected to the liquid treating chambers 400, respectively, are connected to the collective exhaust pipe 560, the cleaning nozzles 620 are installed at the collective exhaust pipe 560. However, unlike this, the technical idea of the present invention may be applied in a manner in which the cleaning nozzles 620 are introduced into the individual exhaust pipes 520 connected to one liquid treating chamber 400 as illustrated in FIG. 7, and the cleaning nozzles 620 are controlled based on the exhaust pressure applied to the individual exhaust pipe 560 at the downstream of the individual exhaust pipe 560.

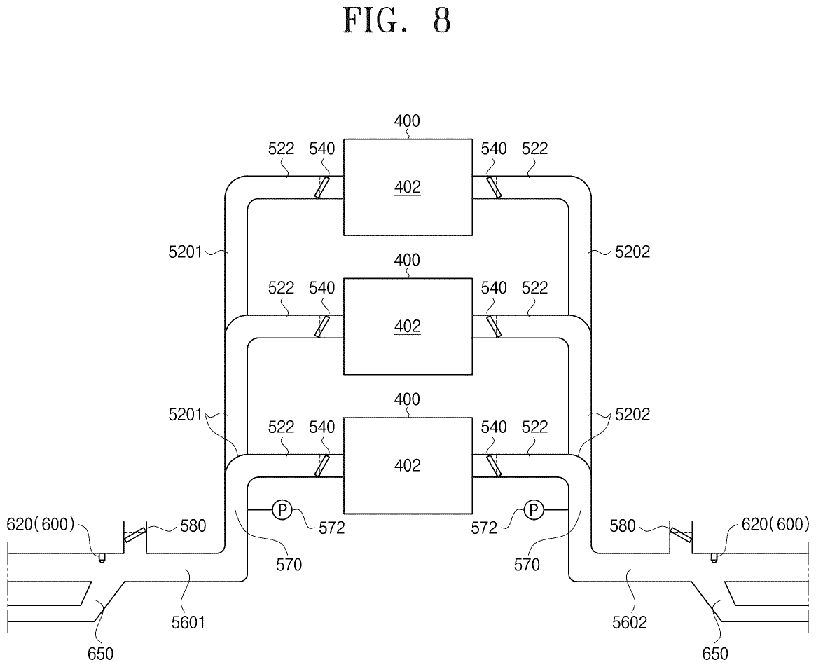

In addition, in the above-described example, the present invention has been described based on the case where one individual exhaust pipe 520 is connected to each liquid treating chamber 400, and these individual exhaust pipes 520 are connected to the collective exhaust pipe 560 as an example. However, unlike this, as illustrated in FIG. 8, two or more individual exhaust pipes 520 may be connected to each liquid treating chamber 400. In this case, the atmosphere in the treatment space 402 may be exhausted through different individual exhaust pipes 520 depending on properties of chemicals used for processing of the substrate W. For example, when two individual exhaust pipes 520 are connected to each liquid treating chamber 400, the atmosphere of the treatment space 400 may be exhausted through a first individual exhaust pipe 5201 when using chemical having an acid component, and the atmosphere of the treatment space 400 may be exhausted through a second individual exhaust pipe 5202 when using chemical having an alkali component. In this case, the first individual exhaust pipes 5201 connected to each liquid treating chamber 400 are connected to the first collective exhaust pipe 5601, and the second individual exhaust pipes 5202 connected to each liquid treating chamber 400 are connected to the second collective exhaust pipe 5202. Furthermore, the cleaning nozzles 620 may be installed in the first collective set exhaust pipe 5601 and the second collective exhaust pipe 5602, respectively.

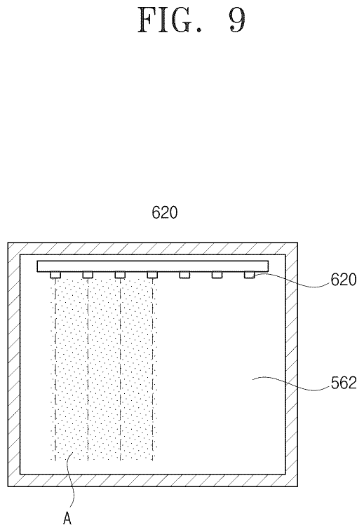

In the above-described example, it has been described that the cleaning nozzle 620 is a two-fluid nozzle, and the amount of gas supplied to the cleaning nozzle 620 is adjusted to adjust an area A occupied by the mist of the cleaning liquid. However, unlike this, as illustrated in FIG. 9, a plurality of cleaning nozzles 620 is provided in a direction perpendicular to the exhaust direction from the collective exhaust passage 562, and the number of cleaning nozzles 620 through which the cleaning liquid is discharged may be controlled in order to adjust the area A occupied by the cleaning liquid.

In the above-described exemplary embodiment, the present invention has been described that the outside air introduction unit 580 is provided in a single unit upstream from the cleaning nozzle 620. However, this is illustrative and the present invention is not limited thereto. The outside air introduction unit 580 may be provided downstream from the cleaning nozzle 620.

In the above exemplary embodiment, the present invention has been described based on the structure in which the outside air introduction unit 580 is provided to the collective exhaust pipe 560 as an example. However, the outside air introduction unit 580 may not be provided to the collective exhaust pipe 560.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. An apparatus for processing a substrate, the apparatus comprising:
a plurality of liquid treating chambers that have a treatment space and supply a treatment liquid to a substrate disposed in the treatment space to perform liquid treatment on the substrate; and
an exhaust unit for exhausting gas in the treatment space of the plurality of liquid treating chambers,
wherein the exhaust unit includes:
a plurality of individual exhaust pipes connected to the liquid treating chambers, respectively, and each having a separate exhaust passage through which gas exhausted from the treatment space flows;
a plurality of exhaust dampers installed in the plurality of individual exhaust pipes, respectively, to control opening rates of the individual exhaust passages;
a collective exhaust pipe connected with the plurality of individual exhaust pipes, and having a collective exhaust passage through which gas exhausted through the plurality of individual exhaust pipes flows;
a cleaning liquid supply unit having a cleaning nozzle that is provided to the collective exhaust pipe and that supplies a mist of the cleaning liquid to form a liquid curtain by the cleaning liquid in the collective exhaust passage;
a cleaning liquid discharge pipe connected to the collective exhaust pipe and discharging the cleaning liquid supplied from the cleaning liquid supply unit to the collective exhaust passage; and
a controller for controlling the cleaning liquid supply unit, and
the controller controls the cleaning liquid supply unit to supply the mist of the cleaning liquid from the cleaning liquid supply unit in an abnormal exhaust state in which exhaust pressure applied to a point where the individual exhaust pipes are connected from upstream in the collective exhaust pipe is higher than a set pressure.

2. The apparatus of claim 1, wherein the exhaust unit further includes an outside air introduction unit provided in the collective exhaust pipe to introduce outside air into the collective exhaust passage.

3. The apparatus of claim 2, wherein the controller controls the cleaning liquid supply unit to adjust an area occupied by the mist in a cross section perpendicular to a length direction of the collective exhaust pipe in the collective exhaust passage based on a magnitude of a difference between the exhaust pressure and the set pressure.

4. The apparatus of claim 3, wherein the cleaning nozzle is a two-fluid nozzle that supplies the cleaning liquid and gas for misting the cleaning liquid, and
the controller controls the cleaning liquid supply unit to adjust the pressure of the gas to adjust the area occupied by the mist of the cleaning liquid discharged from the cleaning nozzle.

5. The apparatus of claim 2, wherein the controller first controls an opening rate of the outside air introduction unit before supplying the mist of the cleaning liquid when the exhaust pressure is higher than the set pressure, and controls the cleaning liquid supply unit to supply the mist of the cleaning liquid when the exhaust pressure is higher than the set pressure even after the opening rate of the outside air introduction unit is maximum.

6. The apparatus of claim 2, wherein the controller first controls an opening rate of the exhaust damper before supplying the mist of the cleaning liquid when the exhaust pressure is higher than the set pressure, and controls the cleaning liquid supply unit to supply the mist of the cleaning liquid when the exhaust pressure is higher than the set pressure even after the opening rate of the exhaust damper is maximum.

7. The apparatus of claim 2, wherein the controller first controls an opening rate of the outside air introduction unit and an opening rate of the exhaust damper before supplying the mist of the cleaning liquid when the exhaust pressure is higher than the set pressure, and controls the cleaning liquid supply unit to supply the mist of the cleaning liquid when the exhaust pressure is higher than the set pressure even after the opening rate of the outside air introduction unit and the opening rate of the exhaust damper are maximum.

8. The apparatus of claim 4, wherein the controller controls the cleaning liquid supply unit so that the pressure of the gas increases as the difference between the exhaust pressure and the set pressure increases.

9. The apparatus of claim 4, wherein the outside air introduction unit is located upstream from the cleaning nozzle and is located downstream from the point where the individual exhaust pipes are connected.

10. The apparatus of claim 1, wherein the controller further controls the cleaning liquid supply unit to periodically supply the mist of the cleaning liquid during processing of the substrate in the liquid treating chamber in a normal exhaust state in which the exhaust pressure is equal to the set pressure.

11. The apparatus of claim 1, wherein the cleaning nozzle and the cleaning liquid discharge pipe are disposed to face each other in a vertical direction.

12. The apparatus of claim 1, wherein the cleaning liquid discharge pipe includes:
a liquid inlet portion including an entrance of the cleaning liquid discharge pipe; and
a discharge pipe portion extending from an end of the liquid inlet portion and having a constant passage area along a longitudinal direction thereof, and
the liquid inlet portion is provided to gradually expand a cross-sectional area in a direction from the discharge pipe portion toward the entrance of the cleaning liquid discharge pipe.

13. An apparatus for processing a substrate, the apparatus comprising:
a liquid treating chamber that has a treatment space and supplies a treatment liquid to a substrate disposed in the treatment space to perform liquid treatment on the substrate; and
an exhaust unit for exhausting gas in the treatment space of the liquid treating chamber,
wherein the exhaust unit includes:
an individual exhaust pipe connected to the liquid treating chamber and having an exhaust passage through which gas exhausted from the treatment space flows;
an exhaust damper installed in the individual exhaust pipe to control an opening rate of the individual exhaust passage;
a cleaning liquid supply unit having a cleaning nozzle that is provided to the individual exhaust pipe and that supplies a mist of the cleaning liquid to form a liquid curtain by the cleaning liquid in the individual exhaust passage;
a cleaning liquid discharge pipe connected to the individual exhaust pipe and discharging the cleaning liquid supplied from the cleaning liquid supply unit to the individual exhaust passage; and
a controller for controlling the cleaning liquid supply unit, and
the controller controls the cleaning liquid supply unit to supply the mist of the cleaning liquid from the cleaning liquid supply unit to the individual exhaust passage in an abnormal exhaust state, in which an exhaust pressure applied to the individual exhaust pipe downstream from the exhaust damper in the individual exhaust passage of the individual exhaust pipe is higher than a set pressure.

14. The apparatus of claim 13, wherein the exhaust unit further includes an outside air introduction unit provided in the individual exhaust pipe to introduce outside air into the individual exhaust passage.

15. The apparatus of claim 14, wherein the controller controls the cleaning liquid supply unit to adjust an area occupied by the mist of the cleaning liquid supplied from the cleaning nozzle in a cross section perpendicular to a length direction of the individual exhaust passage in the individual exhaust passage based on a magnitude of a difference between the exhaust pressure and the set pressure.

16. The apparatus of claim 15, wherein the cleaning nozzle is a two-fluid nozzle that supplies the cleaning liquid and gas for misting the cleaning liquid, and
the controller controls the cleaning liquid supply unit to adjust the pressure of the gas to adjust the area occupied by the mist of the cleaning liquid discharged from the cleaning nozzle.

17. The apparatus of claim 14, wherein the outside air introduction unit is located upstream from the cleaning nozzle and is located downstream from the exhaust damper.

18. The apparatus of claim 14, wherein the cleaning liquid discharge pipe includes:
a liquid inlet portion including an entrance of the cleaning liquid discharge pipe; and
a discharge pipe portion extending from an end of the liquid inlet portion and having a constant passage area along a longitudinal direction thereof, and
an area of the entrance of the cleaning liquid discharge pipe is provided larger than an area of a passage of the discharge pipe portion, and
the cleaning nozzle and the cleaning liquid discharge pipe are disposed to face each other in a vertical direction.

19. The apparatus of claim 14, wherein the controller controls the cleaning liquid supply unit to periodically supply the mist of the cleaning liquid during processing of the substrate in the liquid treating chamber in a normal exhaust state in which the exhaust pressure is equal to the set pressure.

20. An apparatus for processing a substrate, the apparatus comprising:
a plurality of liquid treating chambers that have a treatment space and supply a treatment liquid to a substrate disposed in the treatment space to perform liquid treatment on the substrate; and
an exhaust unit for exhausting gas in the treatment space of the plurality of liquid treating chambers,
wherein the exhaust unit includes:
a plurality of individual exhaust pipes connected to the liquid treating chambers, respectively, and each having a separate exhaust passage through which gas exhausted from the treatment space flows;
a plurality of exhaust dampers installed in the plurality of individual exhaust pipes to control opening rates of the individual exhaust passages, respectively;
a collective exhaust pipe connected with the plurality of individual exhaust pipes, and having a collective exhaust passage through which gas exhausted through the plurality of individual exhaust pipes flows;
an outside air introduction unit provided in the collective exhaust pipe and introducing outside air into the collective exhaust passage;
a cleaning liquid supply unit with a cleaning nozzle that is provided to the collective exhaust pipe and that supplies a mist of the cleaning liquid to form a liquid curtain by the cleaning liquid in the collective exhaust passage;
a cleaning liquid discharge pipe connected to the collective exhaust pipe and discharging the cleaning liquid supplied from the cleaning liquid supply unit to the collective exhaust passage; and
a controller for controlling the cleaning liquid supply unit, and
wherein the controller controls the cleaning liquid supply unit to supply the mist of the cleaning liquid from the cleaning liquid supply unit in an abnormal exhaust state in which exhaust pressure applied to a point where the individual exhaust pipes are connected from upstream in the collective exhaust pipe is higher than a set pressure, and controls the cleaning liquid supply unit to periodically supply the mist of the cleaning liquid during processing of the substrate in the liquid treating chamber in a normal exhaust state in which the exhaust pressure is equal to the set pressure.
